(19) United States
(12) Patent Application Publication
(10) Pub. No.: US 2023/0301199 A1
(43) Pub. Date: Sep. 21, 2023

(54) MAGNETIC TUNNEL JUNCTION STRUCTURE AND MAGNETIC MEMORY DEVICE INCLUDING THE SAME

(71) Applicant: Samsung Electronics Co., Ltd., Suwon-si (KR)

(72) Inventors: Young Keun KIM, Seoul (KR); Taehyun KIM, Seongnam-si (KR)

(73) Assignees: Samsung Electronics Co., Ltd., Suwon-si, Gyeonggi-do (KR); KOREA UNIVERSITY RESEARCH AND BUSINESS FOUNDATION, Seoul (KR)

(21) Appl. No.: 17/829,636

(22) Filed: Jun. 1, 2022

(30) Foreign Application Priority Data
Mar. 21, 2022 (KR) 10-2022-0034613

(51) Int. Cl. H01L 43/02; H01L 27/22

(52) U.S. Cl. CPC H01L 43/02; H01L 27/222; H01L 43/10

(57) ABSTRACT

Disclosed are a magnetic tunnel junction structure and a magnetic memory device including the same. The magnetic tunnel junction structure may include a first spacer layer, a first magnetic layer on the first spacer layer, and a second spacer layer on the first magnetic layer. The first spacer layer and the second spacer layer may include a same material, and a thickness of the first spacer layer may range from 1 nm to 3.5 nm.

### CROSS-REFERENCE TO RELATED APPLICATIONS

This U.S. non-provisional patent application claims priority under 35 U.S.C. § 119 to Korean Patent Application No. 10-2022-0034613, filed on Mar. 21, 2022 in the Korean Intellectual Property Office, the entire contents of which are hereby incorporated by reference.

### BACKGROUND

The present disclosure relates to a magnetic tunnel junction structure and/or a magnetic memory device including the same, and, in particular to, a magnetic tunnel junction structure using an asymmetric exchange interaction and/or a magnetic memory device including the same.

Due to the increased demand for electronic devices with a fast speed and/or a low power consumption, memory devices embedded in the electronic devices may require a fast operating speed and/or a low operating voltage. Magnetic memory devices have been suggested to satisfy such requirements. For example, the magnetic memory device may have reduced latency and/or non-volatility, and thus, the magnetic memory devices are emerging as next-generation memory devices.

The magnetic memory device is a memory device including a magnetic tunnel junction (MTJ) structure. The magnetic tunnel junction structure may include a pair of magnetic layers and an insulating layer therebetween, and a resistance of the magnetic tunnel junction structure may vary depending on a magnetization direction of each of the magnetic layers. In detail, the resistance of the magnetic tunnel junction structure may be high when the magnetization directions of the magnetic layers are antiparallel to each other and may be low when the magnetization directions of the magnetic layers are parallel to each other. This difference in the resistance of the magnetic tunnel junction structure may be used to write and read data in the magnetic memory device.

### SUMMARY

An embodiment of inventive concepts provides a spin-orbit-torque magnetic memory device having a high integration density and/or an improved reliability property.

According to an embodiment of inventive concepts, a magnetic tunnel junction structure may include a first spacer layer, a first magnetic layer on the first spacer layer, and a second spacer layer on the first magnetic layer. The first spacer layer and the second spacer layer may include a same material, and a thickness of the first spacer layer may range from 1 nm to 3.5 nm.

According to an embodiment of inventive concepts, a magnetic memory device may include a substrate, a metal layer on the substrate, a magnetic tunnel junction structure on the metal layer, a bottom electrode contact in contact with the metal layer, a selection element connected to the metal layer through the bottom electrode contact and configured to selectively control a current flow, a read line connected to an upper portion of the magnetic tunnel junction structure, and a write line connected to the metal layer. The magnetic tunnel junction structure may include a first spacer layer, a first magnetic layer on the first spacer layer, and a second spacer layer on the first magnetic layer. The first spacer layer and the second spacer layer may include a same material, and a thickness of the first spacer layer may range from 1 nm to 3.5 nm.

### BRIEF DESCRIPTION OF THE DRAWINGS

FIG. 1 is a conceptual diagram illustrating a unit memory cell of a magnetic memory device according to an embodiment of inventive concepts.

FIG. 2 is a sectional view illustrating a magnetic memory device according to an embodiment of inventive concepts.

FIGS. 3A to 8 are graphs illustrating a magnetic property and/or an interface property of a magnetic tunnel junction structure according to an embodiment of inventive concepts.

### DETAILED DESCRIPTION

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Example embodiments of inventive concepts will now be described more fully with reference to the accompanying drawings, in which example embodiments are shown.

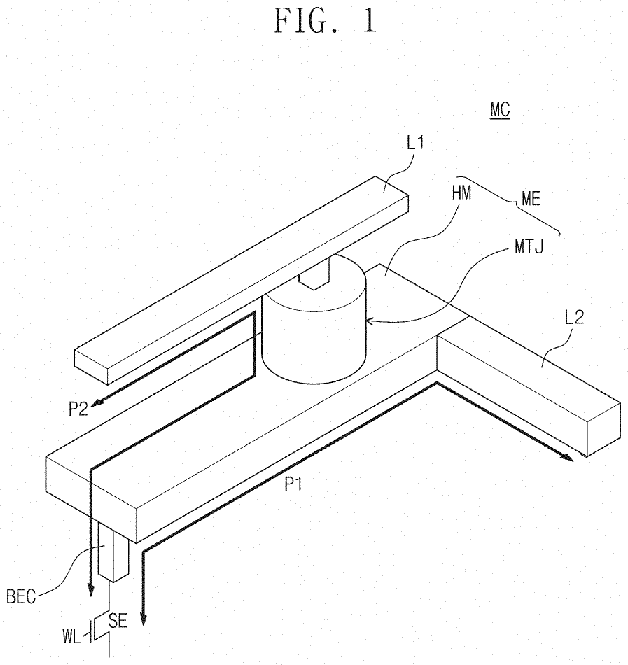

FIG. 1 is a conceptual diagram illustrating a unit memory cell of a magnetic memory device according to an embodiment of inventive concepts.

Referring to FIG. 1, a unit memory cell MC may include a word line WL, a read line L1, a write line L2, a memory element ME, and a selection element SE. The memory element ME may be connected to the read line L1 and the selection element SE and provided between the read line L1 and the selection element SE. The memory element ME may be electrically connected in series to the read line L1 and the selection element SE. The read line L1 may be provided to cross the word line WL, when viewed in a plan view. A plurality of unit memory cells MC may be two- or three-dimensionally arranged. The unit memory cells MC may be two- or three-dimensionally arranged to form a memory cell array. The memory cell array may be connected to a decoder and a driver, such as a decoder circuit and a driver circuit.

The unit memory cell MC may further include a bottom electrode contact BEC between the memory element ME and the selection element SE. In an embodiment, a plurality of bottom electrode contacts BEC may be provided, and in this case, at least one of the bottom electrode contacts BEC may not be connected to the selection element SE. In an embodiment, the bottom electrode contact BEC may be formed of or include at least one of metallic materials (e.g., titanium, tantalum, and tungsten), conductive metal nitride materials (e.g., titanium nitride and tantalum nitride), doped semiconductor materials (e.g., doped silicon, doped germanium, and doped silicon-germanium), or metal-semiconductor compounds (e.g., metal silicide).

However, for convenience in description, the following description will refer to one memory element ME. The memory element ME may be a variable resistance device whose resistance can be switched to one of at least two values, depending on an electric pulse applied thereto. The memory element ME may be provided in a thin film structure. An electric resistance of the memory element ME may be changed using a spin-orbit torque (SOT) produced by a current. The memory element ME may be formed of or include at least one of ferromagnetic materials and/or antiferromagnetic materials.

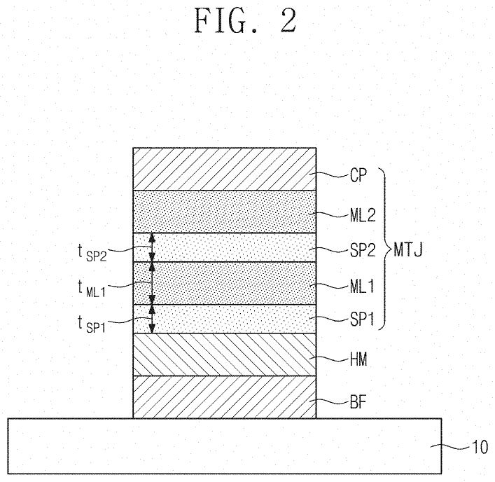

In detail, the memory element ME may include a magnetic tunnel junction structure MTJ and a metal layer HM. The magnetic tunnel junction structure MTJ may include magnetic layers having different properties, as will be described with reference to FIG. 2. One of the magnetic layers may be a free layer whose magnetization direction is freely changed by a current flow, and the other may be a fixed layer whose magnetization direction is fixed regardless of a current flow. In an embodiment, a magnetic layer, which is relatively close to the metal layer HM, may be used as the free layer, and a magnetic layer, which is relatively distant from the metal layer HM, may be used as the fixed layer. An electric resistance of the magnetic tunnel junction structure MTJ may depend on a magnetization direction of the free layer and a magnetization direction of the fixed layer. For example, the electric resistance of the magnetic tunnel junction structure MTJ may be higher when the magnetization directions of the free and fixed layers are antiparallel to each other than when the magnetization directions of the free and fixed layers are parallel to each other. The electric resistance of the magnetic tunnel junction structure MTJ may be controlled by adjusting the magnetization direction of the free layer. A change in the electric resistance of the magnetic tunnel junction structure MTJ may be used to store data in the unit memory cell MC.

If a current flows through a first path P1, the magnetization direction of the free layer of the magnetic tunnel junction structure MTJ may be changed. The first path P1 may include a path that is substantially parallel to a top surface of the free layer. The first path P1 may be a path that is connected from the selection element SE to the write line L2 through one of the bottom electrode contacts BEC and the metal layer HM. Alternatively, the first path P1 may be a path that is connected from the write line L2 to the selection element SE through the metal layer HM and one of the bottom electrode contacts BEC.

If a current flows through the first path P1, a spin orbit interaction of an electron in the metal layer HM may result in a spin Hall effect (SHE) and a Rashba effect (RE). The spin orbit interaction may mean an interaction of an electron's spin with its orbital motion. The spin Hall effect may mean a spin accumulation on a surface of a conductor caused by the spin orbit interaction. The Rashba effect may mean a change of a spin state of an electron in a non-magnetic material caused by a potential difference. The Rashba effect may be enhanced by asymmetry at an interface between the metal layer HM and the free layer. The spin Hall effect and the Rashba effect may accumulate spin-polarized electrons in a region adjacent to the free layer. The accumulated electrons may exert a spin orbit torque on the free layer. When a current passing through the metal layer HM has a specific current density (e.g., greater than a critical current density (Jo)), a spin orbit torque may be exerted on the free layer to change the magnetization direction of the free layer. In an embodiment, the change of the magnetization direction of the free layer may be used for a write operation. In other words, data may be stored in the magnetic tunnel junction structure MTJ by a process of changing the magnetization direction of the free layer.

If a current flows through a second path P2, it may be possible to read the stored data. The second path P2 may include a path that is substantially normal to the top surface of the free layer. For example, the second path P2 may be a path that is connected from the read line L1 to the selection element SE through the magnetic tunnel junction structure MTJ and the metal layer HM. When the current flows through the second path P2, the resistance of the magnetic tunnel junction structure MTJ may be measured. A current flowing through the magnetic tunnel junction structure MTJ may be used for a read operation.

The selection element SE may be configured to selectively control a current flow. For example, the selection element SE may be one of a diode, a PNP bipolar transistor, an NPN bipolar transistor, an NMOS field effect transistor, and a PMOS field effect transistor. In the case where one of the selection element SE is a diode that is a two-terminal device, one of the illustrated lines may be omitted. However, FIG. 1 illustrates an example of ways of connecting the selection element SE to the memory element ME, but inventive concepts are not limited to this example; for example, the selection element SE may be connected to the memory element ME in a different manner.

FIG. 2 is a sectional view illustrating a magnetic memory device according to an embodiment of inventive concepts.

Referring to FIG. 2, a magnetic memory device according to an embodiment of inventive concepts may include a metal layer HM and a magnetic tunnel junction structure MTJ provided on a substrate 10. The substrate 10 may be a semiconductor substrate provided with a plurality of selection elements SE (e.g., see FIG. 1) and a plurality of bottom electrode contacts BEC (e.g., see FIG. 1). In an embodiment, the substrate 10 may be formed of or include silicon, germanium, or silicon-germanium.

The magnetic memory device may further include a buffer layer BF between the substrate 10 and the metal layer HM. The buffer layer BF may include a material capable of improving a crystalline property of the metal layer HM and an adhesion strength between the substrate 10 and the metal layer HM. The buffer layer BF may be formed of or include a heavy metal material whose atomic number is greater than or equal to 30. The buffer layer BF may be formed of or include a material different from the metal layer HM. In an embodiment, the buffer layer BF may be formed of or include tantalum (Ta), but inventive concepts are not limited to this example.

The metal layer HM may be formed of or include a material which can realize a large magnitude of spin orbit interaction when there is a large amount of current. For example, the metal layer HM may be formed of or include at least one of heavy metals whose atomic number is greater than or equal to 30. At least a fraction of a current may flow in a direction that is substantially parallel to a top surface of the metal layer HM. A write operation may be performed using the current flowing through the metal layer HM. In an embodiment, the metal layer HM may be formed of or include at least one of tantalum (Ta), platinum (Pt), bismuth (Bi), titanium (Ti), or tungsten (W).

The magnetic tunnel junction structure MTJ may include a first spacer layer SP1, a first magnetic layer ML1, a second spacer layer SP2, a second magnetic layer ML2, and a capping layer CP, which are sequentially stacked on the metal layer HM. In an embodiment, the magnetic tunnel junction structure MTJ may be provided in plural, and the magnetic tunnel junction structures MTJ may be arranged in an array shape on the substrate 10. The magnetic tunnel junction structures MTJ may not be directly connected to each other and may be used to store respective data independently. However, one of the magnetic tunnel junction structures MTJ will be described below, for convenience in description.

The first spacer layer SP1 may be provided between the metal layer HM and the first magnetic layer ML1. The second spacer layer SP2 may be provided between the first magnetic layer ML1 and the second magnetic layer ML2. The first and second spacer layers SP1 and SP2 may be formed of or include the same material. In other words, an interface property between the first spacer layer SP1 and the first magnetic layer ML1 may be substantially the same as an interface property between the first magnetic layer ML1 and the second spacer layer SP2. In an embodiment, the first and second spacer layers SP1 and SP2 may include an oxide or nitride material that contains at least one element selected from the group consisting of magnesium (Mg), aluminum (Al), silicon (Si), titanium (Ti), zinc (Zn), and boron (B).

In an embodiment, the first and second spacer layers SP1 and SP2 may include one element of 3d, 4d, and 5d transition metals. For example, the first and second spacer layers SP1 and SP2 may include iridium (Ir), ruthenium (Ru), rhodium (Rh), copper (Cu), chromium (Cr), rhenium (Re), or vanadium (V).

A thickness t_{SP1} of the first spacer layer SP1 may be smaller than a thickness of the metal layer HM. For example, the thickness t_{SP1} of the first spacer layer SP1 may range from about 1 nm to about 3.5 nm. In the case where the first spacer layer SP1 is provided to have such a thickness (e.g., about 1 nm to 3.5 nm), it may be possible to realize the Dzyaloshinskii-Moriya interaction (DMI) between the metal layer HM and the first magnetic layer ML1 as well as a tunnel magnetoresistance (TMR) property of the first magnetic layer ML1, as will be described below, and this may make it possible to realize a magnetic memory device with a high operation speed and a low power consumption property. In detail, owing to the DMI between the metal layer HM and the first magnetic layer ML1, it may be possible to reduce an energy consumed in a writing operation on the magnetic memory device. In addition, by adjusting the thickness of the first spacer layer SP1, it may be possible to control a magnitude of the DMI energy between the metal layer HM and the first magnetic layer ML1. Here, the DMI may be one of asymmetric exchange interactions, similar to the Ruderman-Kittel-Kasuya-Yosida (RKKY) interaction (e.g., that can be expressed by a formula describing the RKKY interaction).

A thickness t_{SP2} of the second spacer layer SP2 may be smaller than the thickness of the metal layer HM. The thickness t_{SP2} of the second spacer layer SP2 may be smaller than a thickness t_{ML1} of the first magnetic layer ML1. In an embodiment, the thickness t_{SP2} of the second spacer layer SP2 may be smaller than the thickness t_{SP1} of the first spacer layer SP1, but inventive concepts are not limited to this example. For example, the thickness t_{SP2} of the second spacer layer SP2 may be larger than or equal to the thickness t_{SP1} of the first spacer layer SP1.

The first magnetic layer ML1 may be provided between the first and second spacer layers SP1 and SP2. The second magnetic layer ML2 may be provided between the second spacer layer SP2 and the capping layer CP. The first and second magnetic layers ML1 and ML2 may include at least one of materials having an interface perpendicular magnetic anisotropy. The magnetic anisotropy may mean a property of a ferromagnetic material, in which a specific direction is preferred when spins are aligned by a magnetic field. In an embodiment, the first and second magnetic layers ML1 and ML2 may contain at least one of cobalt (Co), iron (Fe), or nickel (Ni). For example, the first and second magnetic layers ML1 and ML2 may further include at least one element selected from the group of non-magnetic materials including boron (B), zinc (Zn), aluminum (Al), titanium (Ti), ruthenium (Ru), tantalum (Ta), silicon (Si), silver (Ag), gold (Au), copper (Cu), carbon (C), and nitrogen (N). As an example, the first and second magnetic layers ML1 and ML2 may include CoFe or NiFe and, in an embodiment, may further include boron (B). In an embodiment, the first and second magnetic layers ML1 and ML2 may further include at least one of materials (e.g., titanium (Ti), aluminum (Al), silicon (Si), magnesium (Mg), tantalum (Ta), and silicon (Si)) capable of lowering a saturation magnetization.

The thickness t_{ML1} of the first magnetic layer ML1 may be smaller than the thickness of the metal layer HM. The thickness t_{ML1} of the first magnetic layer ML1 may be larger than the thickness t_{SP2} of the second spacer layer SP2. In an embodiment, the thickness t_{ML1} of the first magnetic layer ML1 may be smaller than the thickness t_{SP1} of the first spacer layer SP1, but inventive concepts are not limited to this example. For example, the thickness t_{ML1} of the first magnetic layer ML1 may be larger than or equal to the thickness t_{SP1} of the first spacer layer SP1.

The capping layer CP may be provided on the second magnetic layer ML2. The capping layer CP may fully cover the second magnetic layer ML2. The capping layer CP may be formed of or include a material capable of preventing or suppressing the second magnetic layer ML2 and/or the second spacer layer SP2 from being oxidized. For example, the capping layer CP may include a heavy metal material whose atomic number is greater than or equal to 30. The capping layer CP may be formed of or include a material different from the metal layer HM. The capping layer CP may be formed of or include the same material as the buffer layer BF. In an embodiment, the capping layer CP may be formed of or include tantalum (Ta), but inventive concepts are not limited to this example.

In an embodiment, the magnetic tunnel junction structure MTJ may further include a polarization enhancement layer, which is interposed between the first magnetic layer ML1 and the second spacer layer SP2 and/or between the second spacer layer SP2 and the second magnetic layer ML2. The polarization enhancement layer may be configured to enhance spin polarization and tunnel magnetoresistance (TMR) properties of the first and second magnetic layers ML1 and ML2. In an embodiment, the polarization enhancement layer may be formed of or include at least one of iron (Fe), iron (Fe) alloys having a body-centered cubic (BCC) structure, CoFeB-based amorphous alloys, and alloys having an L21 crystal structure.

The first and second spacer layers SP1 and SP2 of the magnetic tunnel junction structure MTJ may be formed by an RF magnetron sputtering process, and the buffer layer BF, the metal layer HM, the first and second magnetic layers ML1 and ML2, and the capping layer CP may be formed by a DC magnetron sputtering process. Each of the layers on the substrate 10 may be thermally annealed at about 300° C. for about 1 hours, after its deposition process.

FIG. 2 illustrates an example, in which the metal layer HM is provided on the substrate 10 and the magnetic tunnel junction structure MTJ including the first spacer layer SP1, the first magnetic layer ML1, the second spacer layer SP2, the second magnetic layer ML2, and the capping layer CP is provided on the metal layer HM, but inventive concepts are not limited to this example. For example, the magnetic tunnel junction structure MTJ, which includes the capping layer CP, the second magnetic layer ML2, the second spacer layer SP2, the first magnetic layer ML1, and the first spacer layer SP1, may be provided on the substrate 10, and the metal layer HM may be provided on the magnetic tunnel junction structure MTJ. In other words, the order of the layers stacked on the substrate 10 may be opposite to that in FIG. 2.

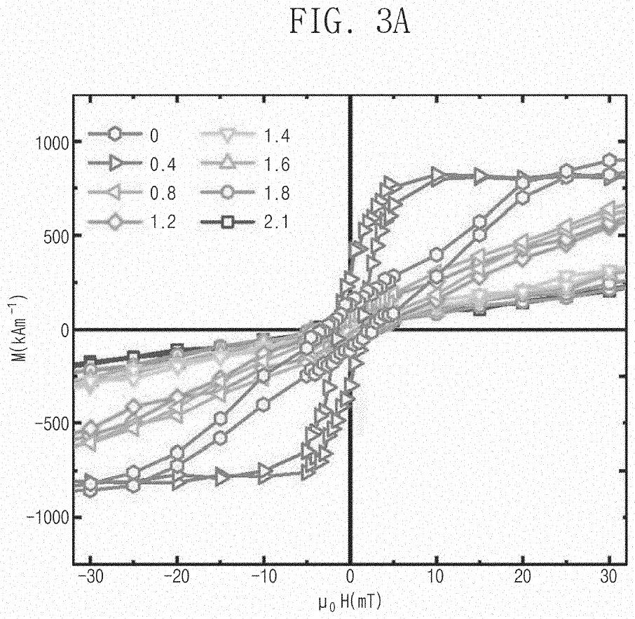

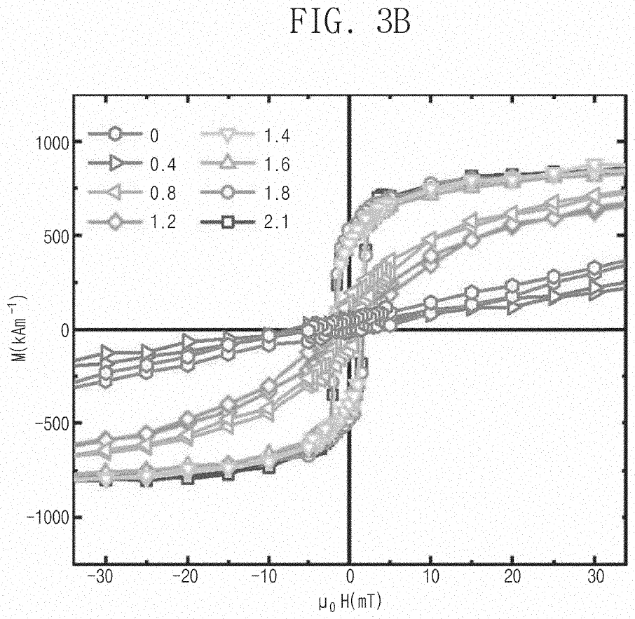

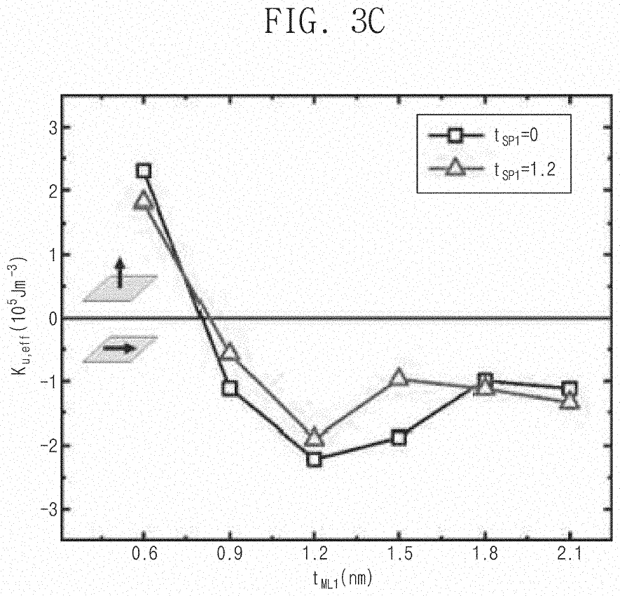

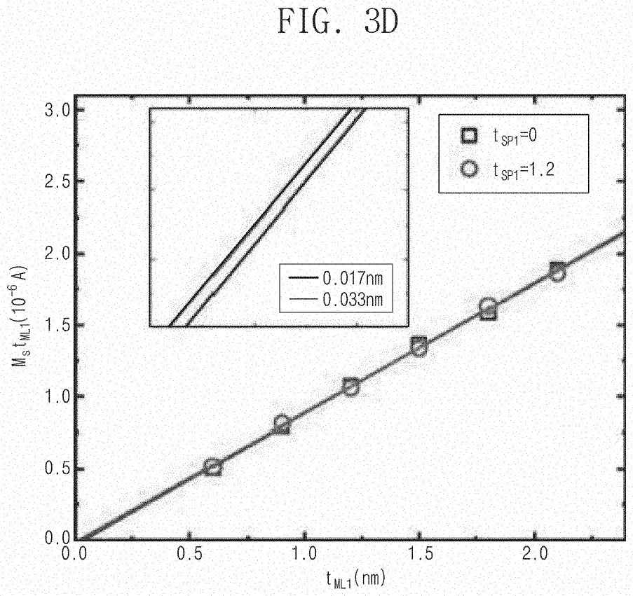

FIGS. 3A to 8 are graphs illustrating a magnetic property and/or an interface property of a magnetic tunnel junction structure according to an embodiment of inventive concepts.

FIGS. 3A to 3D, 4A, 4B, 5, and 6A to 6C are graphs measured from samples, which includes the magnetic tunnel junction structure MTJ composed of the first spacer layer SP1, the first magnetic layer ML1, the second spacer layer SP2, and the capping layer CP (e.g., without the second magnetic layer ML2 of FIG. 2). Here, in the samples, a thickness of the buffer layer BF was about 3 nm, the thickness of the metal layer HM was about 5 nm, the thickness t_{SP2} of the second spacer layer SP2 was about 1 nm, and a thickness of the capping layer CP was about 2 nm. Furthermore, in the samples, the buffer layer BF and the capping layer CP were formed to include tantalum (Ta), the metal layer HM was formed to include platinum (Pt), the first and second spacer layers SP1 and SP2 were formed to include magnesium oxide (MgO), and the first magnetic layer ML1 was formed to include CoFeSiB.

FIGS. 3A and 3B are graphs showing a change in hysteresis loop of the first magnetic layer ML1 caused by a change in the thickness t_{SP1} of the first spacer layer SP1. Here, the thickness t_{ML1} of the first magnetic layer ML1 was about 0.9 nm. In FIGS. 3A and 3B, the horizontal axis represents a magnetic flux density (B=μ₀H) (in unit of mT), and the vertical axis represents a magnetization vector (M) (in unit of kA/m). The hysteresis loops were measured by a vibrating sample magnetometry (VSM), when the thickness t_{SP1} of the first spacer layer SP1 were about 0 nm, about 0.4 nm, about 0.8 nm, about 1.2 nm, about 1.4 nm, about 1.6 nm, about 1.8 nm, and about 2.1 nm. FIG. 3A shows a result measured in an out-of-plane direction, and FIG. 3B shows a result measured in an in-plane direction.

FIGS. 3A and 3B show that as the thickness t_{SP1} of the first spacer layer SP1 increases, the magnetic anisotropy of the first magnetic layer ML1 in the out-of-plane direction is weakened and the magnetic anisotropy in the in-plane direction is strengthened.

FIG. 3C is a graph showing a relationship between a uniaxial anisotropic energy (K_{u,eff}) (in unit of 10⁵ J/m³) and the thickness t_{ML1} (in unit of nm) of the first magnetic layer ML1, measured from samples in which the thicknesses t_{SP1} of the first spacer layers SP1 were different from each other.

FIG. 3C shows that a direction and a magnitude of the magnetic anisotropy can vary depending on the thickness t_{SP1} of the first spacer layer SP1 and the thickness t_{ML1} of the first magnetic layer ML1.

FIG. 3D is a graph for calculating effective saturation magnetization values Mₛ^{eff}, measured from samples in which the thicknesses t_{SP1} of the first spacer layers SP1 were different from each other. In FIG. 3D, the horizontal axis represents the thickness t_{ML1} of the first magnetic layer ML1, and the vertical axis represents a product of the thickness t_{ML1} of the first magnetic layer ML1 and the effective saturation magnetization value Mₛ^{eff} (in unit of 10⁻⁶ A).

Referring to FIG. 3D, the product of the thickness t_{ML1} of the first magnetic layer ML1 and the effective saturation magnetization value Mₛ^{eff} is represented by a first-order function of the thickness t_{ML1} of the first magnetic layer ML1. In other words, the effective saturation magnetization value Mₛ^{eff} was constant for the samples in which the thicknesses t_{SP1} of the first spacer layers SP1 were different from each other. For the thickness t_{SP1} of about 0 nm, the effective saturation magnetization value Mₛ^{eff} was about 912.8 kA/m, and for the thickness t_{SP1} of about 1.2 nm, the effective saturation magnetization value Mₛ^{eff} was about 902.3 kA/m. Furthermore, for the thickness t_{SP1} of about 0 nm, the graph has a magnetically dead point (e.g., having a vanishing magnetic field) at the thickness t_{ML1} of about 0.017 nm, and for the thickness t_{SP1} of about 1.2 nm, the graph has the magnetically dead point at the thickness t_{ML1} of about 0.033 nm.

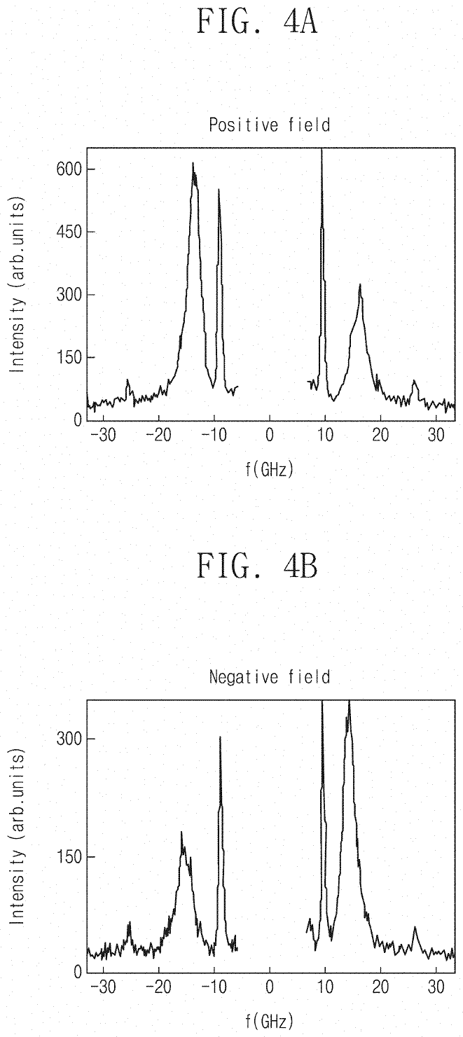

FIGS. 4A and 4B are graphs for calculating a frequency difference (At) between stokes and anti-stokes peaks occurred when a horizontal external magnetic field was applied to the samples. In each of FIGS. 4A and 4B, the horizontal axis represents a frequency (in unit of GHz), and the vertical axis represents a signal intensity. When a direction parallel to a top surface of the substrate 10 in the magnetic memory device of FIG. 2 is defined as a positive direction, FIG. 4A is a result obtained by applying an external magnetic field of the positive direction to a sample, and FIG. 4B is a result of applying an external magnetic field of the negative direction to the sample. FIGS. 4A and 4B are measured using a Brillouin light scattering spectroscopy (BLS).

A process of calculating the frequency difference (At) between the stokes and anti-stokes peaks from the graphs of FIGS. 4A and 4B may include normalizing two graphs of FIGS. 4A and 4B, overlapping a graph, which is obtained by flipping one of the two graphs left and right, with the other graph, and calculating a frequency difference between peaks facing each other.

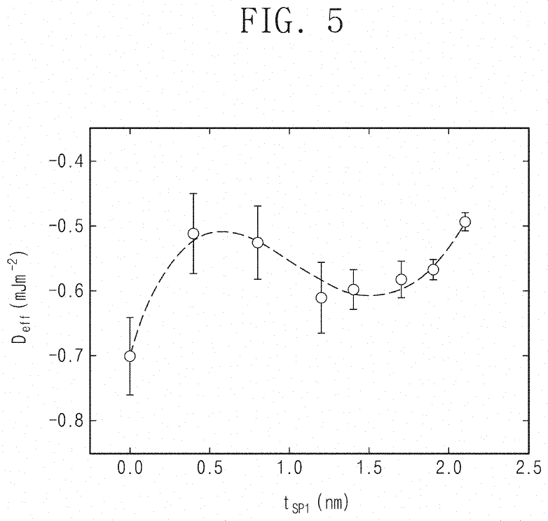

FIG. 5 is a graph showing a relationship between the thickness t_{SP1} of the first spacer layer SP1 and a DMI energy density D_{eff}. Here, by using the following formula 1, the DMI energy density D_{eff} may be obtained from the effective saturation magnetization value Mₛ^{eff} calculated in FIG. 3D and the frequency difference (Δf) between the stokes and anti-stokes peaks obtained using FIGS. 4A and 4B. In FIG. 5, the horizontal axis represents the thickness t_{SP1} of the first spacer layer SP1, and the vertical axis represents the DMI energy density D_{eff} (in unit of mJ/m²).

$$Δ f = {f}_{S} - {f}_{AS} = \frac{2 γ}{π} \frac{{D}_{eff}}{{M}_{s}} {k}_{SW} \qquad [ Formula 1 ]$$

where f_{S} is a frequency corresponding to a stokes peak, f_{AS} is a frequency corresponding to an anti-stokes peak, D_{eff} is a DMI energy density, Mₛ is an effective saturation magnetization value, and k_{SW} is a wavenumber vector of a spin-wave. The DMI energy density D_{eff} can be calculated by substituting the effective saturation magnetization value Ms and the frequency difference (At) into the formula 1.

Referring to FIG. 5, despite the presence of the first spacer layer SP1, the DMI does not disappear, and the DMI energy density exhibits an oscillating behavior depending on the thickness t_{SP1} of the first spacer layer SP1. In detail, as the thickness t_{SP1} of the first spacer layer SP1 increases, the DMI energy density exhibits an oscillating and decreasing behavior.

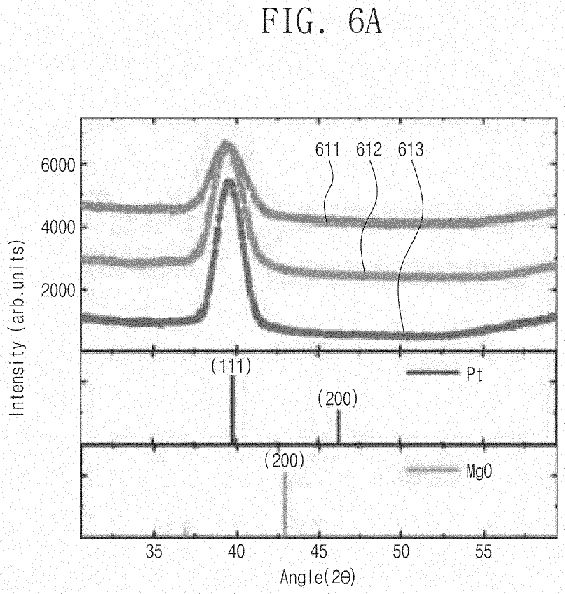

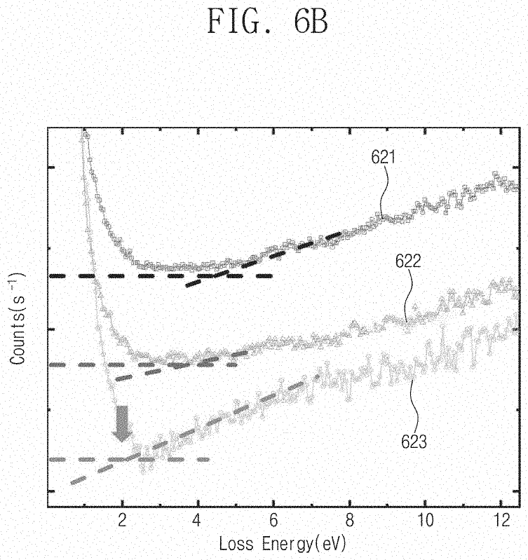

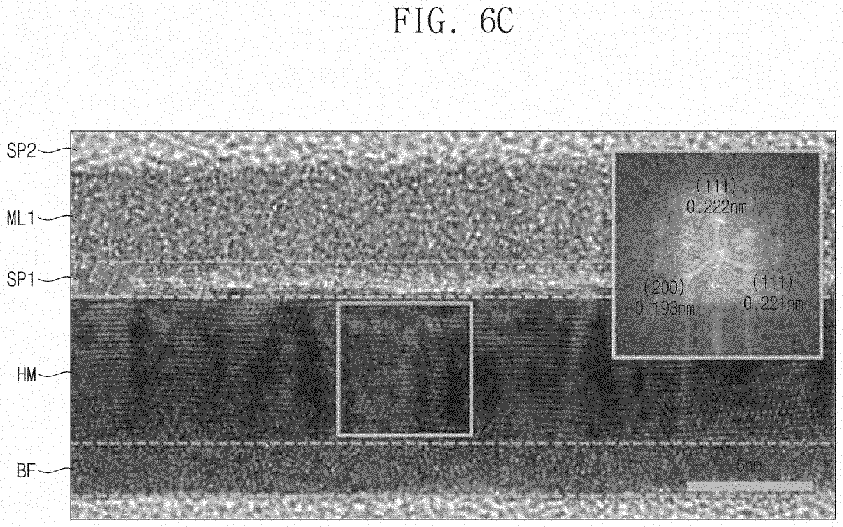

FIGS. 6A, 6B, and 6C are graphs and an image showing structural features of the samples in which the thicknesses t_{SP1} of the first spacer layers SP1 were different from each other. FIG. 6A is a graph showing a result measured using an X-ray diffraction spectroscopy (XRD), FIG. 6B is a graph showing a result measured using a reflection electron energy loss spectroscopy (REELS), and FIG. 6C is an image obtained using a transmission electron microscope (TEM).

In FIG. 6A, a first XRD spectrum 611 was a result measured when the thickness t_{SP1} of the first spacer layer SP1 was about 2.1 nm, a second XRD spectrum 612 was a result measured when the thickness t_{SP1} of the first spacer layer SP1 was about 1.2 nm, and a third XRD spectrum 613 was a result measured when the thickness t_{SP1} of the first spacer layer SP1 was about 0 nm.

In FIG. 6B, a first REELS spectrum 621 was a result measured when the thickness t_{SP1} of the first spacer layer SP1 was about 10 nm, a second REELS spectrum 622 was a result measured when the thickness t_{SP1} of the first spacer layer SP1 was about 2.1 nm, and a third REELS spectrum 623 was a result measured when the thickness t_{SP1} of the first spacer layer SP1 was about 1.2 nm. A reflection electron energy loss E_{g}, at which the count is the minimum, was about 5.18 eV in the first REELS spectrum 621, about 3.95 eV in the second REELS spectrum 622, and about 1.98 eV in the third REELS spectrum 623.

Referring to FIGS. 6A, 6B, and 6C, in the samples in which the thicknesses t_{SP1} of the first spacer layers SP1 were different from each other, the metal layers HM (e.g., platinum (Pt)) had substantially the same crystalline property. In particular, referring to FIG. 6B, as the thickness t_{SP1} of the first spacer layer SP1 decreases, the graph had a decreasing band gap energy.

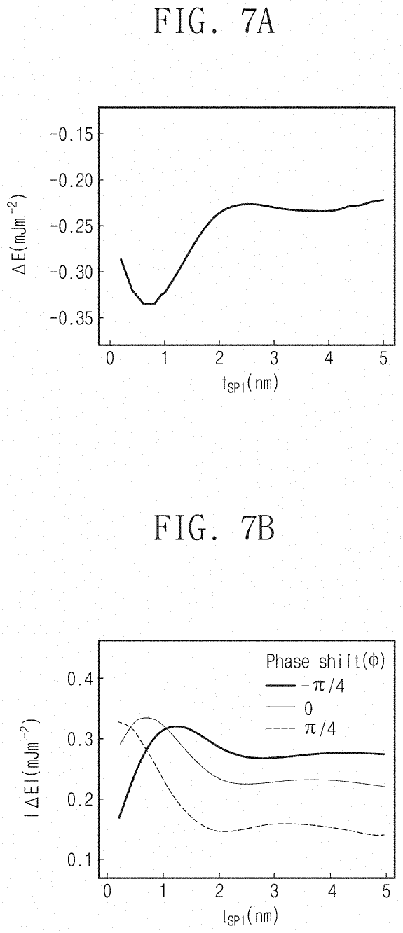

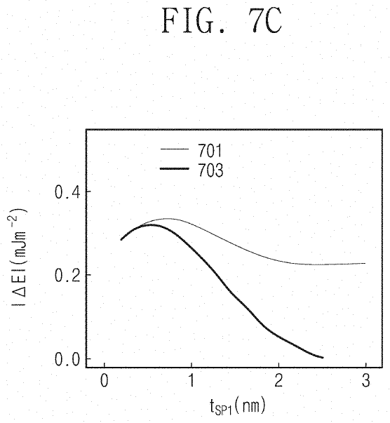

FIG. 7A is a graph showing a relationship between the thickness t_{SP1} of the first spacer layer SP1 and the DMI energy density (AE). Here, the DMI energy density D_{eff} is a result that is theoretically calculated using a formula representing the RKKY interaction. FIG. 7B is a result that is obtained from FIG. 7A in consideration of a phase shift of +π/4 or −π/4. In FIG. 7C, the curve 701 is a result that is calculated for a first experimental example, in which the first spacer layer SP1 includes magnesium oxide (MgO), and the curve 702 is a result that is calculated for a second experimental example, in which the first spacer layer SP1 includes a material having higher conductivity than magnesium oxide (MgO). In FIGS. 7A to 7C, the horizontal axis represents the thickness t_{SP1} of the first spacer layer SP1, and the vertical axis represents the DMI energy density (in unit of mJ/m²).

Referring to FIGS. 7A to 7C, similar to the result of FIG. 5, despite the presence of the first spacer layer SP1, the DMI does not disappear, and the DMI energy density exhibits an oscillating behavior depending on the thickness t_{SP1} of the first spacer layer SP1. In detail, as the thickness t_{SP1} of the first spacer layer SP1 increases, the DMI energy density exhibits an oscillating and decreasing behavior. Referring to FIG. 7C, for the first experimental example 701, in which the first spacer layer SP1 includes magnesium oxide (MgO), despite the increase of the thickness t_{SP1} of the first spacer layer SP1, the DMI energy density can be maintained for a longer time, compared with the second experimental example 703.

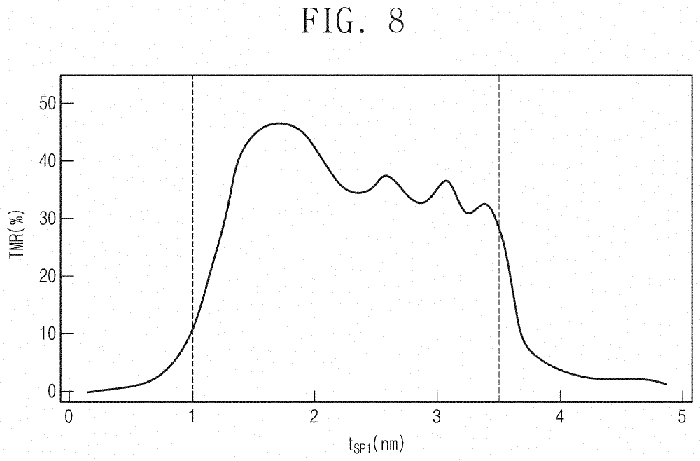

FIG. 8 is a graph showing a relationship between the thickness t_{SP1} of the first spacer layer SP1 and the tunnel magnetoresistance (TMR) property of the first magnetic layer ML1. FIG. 8 is a result obtained from a sample, in which the first spacer layer SP1 in contact with the first magnetic layer ML1 includes magnesium oxide (MgO). In FIG. 8, the horizontal axis represents the thickness t_{SP1} of the first spacer layer SP1, and the vertical axis represents a tunnel magnetoresistance (TMR) ratio (in unit of %).

Referring to FIG. 8 in conjunction with FIGS. 5 and 7A, in the case where the first spacer layer SP1 is provided to have a thickness of about 1 nm to about 3.5 nm, the graph of FIG. 8 shows that the DMI between the metal layer HM and the first magnetic layer ML1 and the tunnel magnetoresistance property of the first magnetic layer ML1 can be maintained to allow for operations of a magnetic memory device.

In a magnetic memory device according to an embodiment of inventive concepts, a first spacer layer, which has a thickness of about 1 nm to about 3.5 nm, may be provided between a first magnetic layer (e.g., free layer) and a metal layer, and thus, it may be possible to improve the Dzyaloshinskii-Moriya interaction (DMI) property between the metal layer as well as the first magnetic layer and a tunnel magnetoresistance (TMR) property of the first magnetic layer. In addition, by adjusting the thickness of the first spacer layer, it may be possible to control a magnitude of the DMI energy between the metal layer and the first magnetic layer. This may make it possible to realize a magnetic memory device with a high operation speed and a low power consumption property.

While example embodiments of inventive concepts have been particularly shown and described, it will be understood by one of ordinary skill in the art that variations in form and detail may be made therein without departing from the spirit and scope of the attached claims.

What is claimed is:

1. A magnetic tunnel junction structure, comprising:
a first spacer layer;
a first magnetic layer on the first spacer layer; and
a second spacer layer on the first magnetic layer,
wherein the first spacer layer and the second spacer layer comprise a same material, and
a thickness of the first spacer layer ranges from 1 nm to 3.5 nm.

2. The magnetic tunnel junction structure of claim 1, wherein
the first spacer layer and the second spacer layer comprise an oxide material or a nitride material, and
the oxide material or the nitride material contains at least one of magnesium (Mg), aluminum (Al), silicon (Si), titanium (Ti), zinc (Zn), and boron (B).

3. The magnetic tunnel junction structure of claim 1, wherein the first spacer layer and the second spacer layer comprise one element selected from 3d transition metals, 4d transition metals, and 5d transition metals.

4. The magnetic tunnel junction structure of claim 1, wherein the thickness of the first spacer layer is larger than a thickness of the second spacer layer.

5. The magnetic tunnel junction structure of claim 1, wherein a thickness of the first magnetic layer is larger than a thickness of the second spacer layer.

6. The magnetic tunnel junction structure of claim 1, further comprising:
a second magnetic layer on the second spacer layer,
wherein the first magnetic layer is configured such that a magnetization direction thereof is changed by a current flow, and
the second magnetic layer is configured such that a magnetization direction thereof is fixed regardless of a current flow.

7. The magnetic tunnel junction structure of claim 6, wherein
the first magnetic layer and the second magnetic layer comprise a first material and a second material,
the first material includes at least one of cobalt (Co), iron (Fe), and nickel (Ni), and
the second material includes at least one of boron (B), zinc (Zn), aluminum (Al), titanium (Ti), ruthenium (Ru), tantalum (Ta), silicon (Si), silver (Ag), gold (Au), copper (Cu), carbon (C), and nitrogen (N).

8. The magnetic tunnel junction structure of claim 1, further comprising:
a capping layer on the second spacer layer.

9. The magnetic tunnel junction structure of claim 8, wherein the capping layer comprises a heavy metal material whose atomic number is greater than or equal to 30.

10. A magnetic memory device, comprising:
a substrate;
a metal layer on the substrate;
a magnetic tunnel junction structure on the metal layer;
a bottom electrode contact in contact with the metal layer;
a selection element connected to the metal layer through the bottom electrode contact and configured to selectively control a current flow;
a read line connected to an upper portion of the magnetic tunnel junction structure; and
a write line connected to the metal layer,
wherein the magnetic tunnel junction structure comprises a first spacer layer, a first magnetic layer on the first spacer layer, and a second spacer layer on the first magnetic layer,
wherein the first spacer layer and the second spacer layer comprise a same material, and
a thickness of the first spacer layer ranges from 1 nm to 3.5 nm.

11. The magnetic memory device of claim 10, wherein
the first spacer layer and the second spacer layer comprise an oxide material or a nitride material, and
the oxide material or the nitride material contains at least one of magnesium (Mg), aluminum (Al), silicon (Si), titanium (Ti), zinc (Zn), and boron (B).

12. The magnetic memory device of claim 10, wherein the first spacer layer and the second spacer layer comprise one element selected from 3d transition metals, 4d transition metals, and 5d transition metals.

13. The magnetic memory device of claim 10, wherein the thickness of the first spacer layer is larger than a thickness of the second spacer layer.

14. The magnetic memory device of claim 10, wherein a thickness of the first magnetic layer is larger than a thickness of the second spacer layer.

15. The magnetic memory device of claim 10, wherein a thickness of the metal layer is larger than the thickness of the first spacer layer and a thickness of the first magnetic layer.

16. The magnetic memory device of claim 10, wherein the metal layer comprises at least one of tantalum (Ta), platinum (Pt), bismuth (Bi), titanium (Ti), or tungsten (W).

17. The magnetic memory device of claim 10, further comprising:
a second magnetic layer on the second spacer layer,
wherein the first magnetic layer is configured such that a magnetization direction thereof is changed by a current flow, and
the second magnetic layer is configured such that a magnetization direction thereof is fixed regardless of a current flow.

18. The magnetic memory device of claim 17, wherein
the first magnetic layer and the second magnetic layer comprise a first material and a second material,
the first material includes at least one of cobalt (Co), iron (Fe), and nickel (Ni),
the second material includes at least one of boron (B), zinc (Zn), aluminum (Al), titanium (Ti), ruthenium (Ru), tantalum (Ta), silicon (Si), silver (Ag), gold (Au), copper (Cu), carbon (C), and nitrogen (N).

19. The magnetic memory device of claim 10, further comprising:
a buffer layer between the substrate and the metal layer; and
a capping layer on the second spacer layer,
wherein each of the buffer layer and the capping layer comprises a heavy metal material whose atomic number is greater than or equal to 30.

20. The magnetic memory device of claim 10, wherein
the magnetic tunnel junction structure is provided in plural to provide a plurality of magnetic tunnel junction structures, and
the plurality of magnetic tunnel junction structures are arranged on the substrate in an array shape and are configured to store respective data independently.
